(19) United States
(12) Patent Application Publication
(10) Pub. No.: US 2011/0227085 A1
(43) Pub. Date: Sep. 22, 2011

(54) SUBSTRATE FOR USE IN DISPLAY PANEL, AND DISPLAY PANEL INCLUDING SAME

(75) Inventors: Wataru Nakamura, Osaka-shi (JP); Kenichi Kitoh, Osaka-shi (JP); Tetsunori Tanaka, Osaka-shi (JP); Takeshi Hara, Osaka-shi (JP); Yuya Nakano, Osaka-shi (JP)

(73) Assignee: SHARP KABUSHIKI KAISHA, Osaka-shi, Osaka (JP)

(21) Appl. No.: 13/130,583

(22) PCT Filed: Nov. 5, 2009
(86) PCT No.: PCT/JP2009/068927

§ 371 Date: May 23, 2011

(30) Foreign Application Priority Data
Dec. 26, 2008 (JP) 2008-334743

(51) Int. Cl. H01L 29/786

(52) U.S. Cl. 257/59; 257/E29.289

(57) ABSTRACT

The present invention is a substrate for use in a display panel. According to the substrate, lines (102, 106, 107, and 113) provided in a display region on the substrate are made up of multiple layers whose uppermost layers (102c, 106c, 107c, and 113c) are each made from (i) an oxide of first metal selected from the group consisting of copper, titanium, and molybdenum or (ii) a nitride of copper. This can prevent external light from being reflected and thereby improve a contrast in a bright room.

### TECHNICAL FIELD

The present invention relates to a substrate for use in a display panel and to a display panel including the substrate.

### BACKGROUND ART

Display panels employing liquid crystals, organic ELs, inorganic ELs, or the like have been increasingly used. Among such display panels, a display panel including a substrate of active matrix type has been widely used. The display panel of this type has a feature that a response speed is high and multiple-tone display is easy.

The display panel thus including the substrate of active matrix type includes (i) an active matrix substrate in which a plurality of pixels are provided in matrix and (ii) a common substrate provided so as to face the active matrix substrate. According the display panel of this type, a display medium such as a liquid crystal layer, an organic EL layer, or the like is sandwiched between the active matrix substrate and the common substrate. In the active matrix substrate, a plurality of gate lines and that of source lines are provided so as to intersect each other, and pixel sections including respective TFTs are provided near respective intersections of the plurality of gate lines and that of the source lines.

Regarding formation of such lines of the active matrix substrate, Patent Literature 1 disclose an etching solution usable in etching of (i) a line having a bi-layer structure in which layers made from copper and titanium are provided or (ii) a layer having a tri-layered structure in which layers made from titanium, copper, and titanium are provided. Patent Literature 2 discloses an etching solution for etching, by single etching, a line made up of two metal layers whose upper layer is made from copper. Patent Literature 3 describes an array substrate for use in a liquid crystal display apparatus, which array substrate includes lines each made up of two metal layers whose upper layer is made from copper.

### CITATION LIST

### Patent Literature 1

U.S. Pat. No. 7,008,548

### Patent Literature 2

Japanese Patent Application Publication, Tokukai, No. 2002-302780 Å (Publication Date: Oct. 18, 2002)

### Patent Literature 3

Japanese Patent Application Publication, Tokukai, No. 2004-133422 Å (Publication Date: Apr. 30, 2004)

### SUMMARY OF INVENTION

### Technical Problem

Employing of such an active matrix substrate of a conventional technique in a display panel poses a problem that external light is reflected by highly reflective metal of lines so that a contrast in a bright room is deteriorated.

The present invention is made in view of the problem, and an object of the invention is to provide (i) a substrate for use in a display panel in which it is possible to prevent external from being reflected and thereby to improve a contrast in a bright room and (ii) a display panel including the substrate (i).

### Solution to Problem

In order to attain the object, a substrate of the present invention for use in a display panel includes a line provided in a display region on the substrate, the line made up of a plurality of layers whose uppermost layer is made from (i) an oxide of a first metal selected from the group consisting of copper, titanium, and molybdenum or (ii) a nitride of copper.

According to the configuration, a reflectance of each of (i) the oxide of copper, titanium, or molybdenum and (ii) the nitride of copper are very smaller than that of metal. This allows the uppermost layer of the line provided in the display region on the substrate to have a smaller reflectance. It is therefore possible to fabricate a display panel in which it is possible to prevent external light from being reflected and thereby to improve a contrast in a bright room.

A display panel of the present invention includes the substrate. It is therefore possible to realize a display panel in which it is possible to prevent external light from being reflected by the line is prevented and thereby to improve a contrast in a bright room is improved.

### Advantageous Effects of Invention

As discussed earlier, a substrate of the present invention for use in a display panel includes a line provided in a display region on the substrate, the line being made up of a plurality of layers whose uppermost layer is made from (i) an oxide of a first metal selected from the group consisting of copper, titanium, molybdenum or (ii) a nitride of copper. This can prevent external light from being reflected by the line and thereby improve a contrast in a bright room.

For a fuller understanding of the nature and advantages of the invention, reference should be made to the ensuing detailed description taken in conjunction with the accompanying drawings.

### BRIEF DESCRIPTION OF DRAWINGS

FIG. 1 is a cross sectional view showing an active matrix substrate in accordance with one embodiment of the present invention.

FIG. 2 is a plan view showing the active matrix substrate in accordance with the embodiment.

FIG. 3 is a cross sectional view showing a gate line 102 in accordance with the embodiment.

FIG. 4 is a cross sectional view showing the active matrix substrate in accordance with the embodiment.

FIG. 5 is a plan view showing the active matrix substrate in accordance with the embodiment.

FIG. 6 is a cross sectional view showing that a step of depositing first metal films is carried out with respect to the active matrix substrate in accordance with the embodiment.

FIG. 7 is a cross sectional view showing that a step of depositing the gate line 102 is carried out with respect to the active matrix substrate in accordance with the embodiment.

FIG. 8 is a cross sectional view showing that a step of depositing a gate insulating film 103 and a semiconductor layer 104 is carried out with respect to the active matrix substrate in accordance with the embodiment.

FIG. 9 is a cross sectional view showing that a step of forming a pattern of the semiconductor layer 104 is carried out with respect to the active matrix substrate in accordance with the embodiment.

FIG. 10 is a cross sectional view showing that a step of depositing second metal films is carried out with respect to the active matrix substrate in accordance with the embodiment.

FIG. 11 is a cross sectional view showing that a step of forming a pattern of a source line 106 is carried out with respect to the active matrix substrate in accordance with the embodiment.

FIG. 12 is a cross sectional view showing that a step of etching a channel section 112 is carried out with respect to the active matrix substrate in accordance with the embodiment.

FIG. 13 is a cross sectional view showing that a step of depositing a passivation film 108 is carried out with respect to the active matrix substrate in accordance with the embodiment.

FIG. 14 is a cross sectional view showing that a step of forming an interlayer insulating film 109 is carried out with respect to the active matrix substrate in accordance with the embodiment.

FIG. 15 is a cross sectional view showing that a step of etching a contact hole section 111 is carried out with respect to the active matrix substrate in accordance with the embodiment.

FIG. 16 is a cross sectional view showing that a step of removing a copper oxide layer 107c is carried out with respect to the active matrix substrate, in accordance with the embodiment.

### DESCRIPTION OF EMBODIMENTS

With reference to the drawings, a display panel is described below in accordance with one embodiment of the present invention. However, the present invention is not limited to this.

The present embodiment discusses a liquid crystal display panel (display panel) that includes a substrate of active matrix type. According to the liquid crystal display panel of the present embodiment, an active matrix substrate (substrate) and a common substrate are combined to each other so that a liquid crystal layer is provided between the active matrix substrate and the common substrate.

<Active Matrix Substrate>

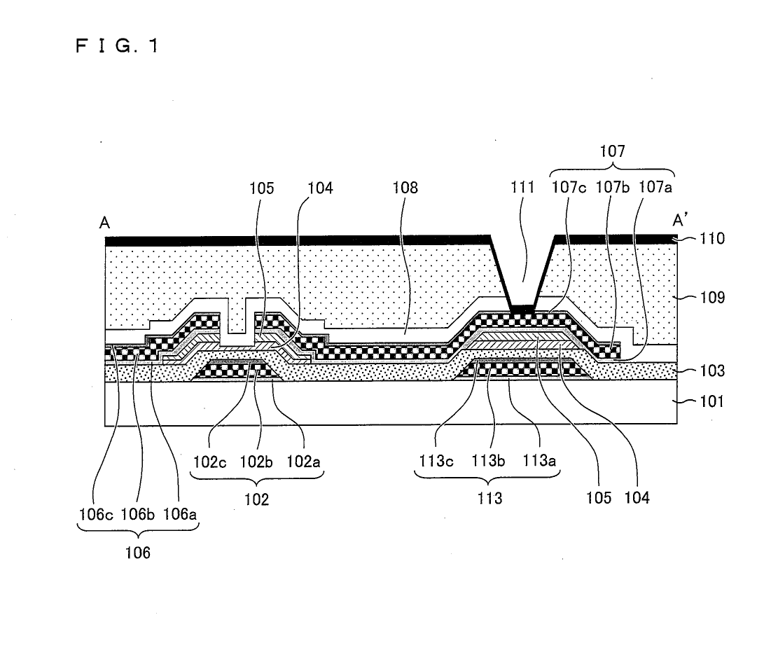

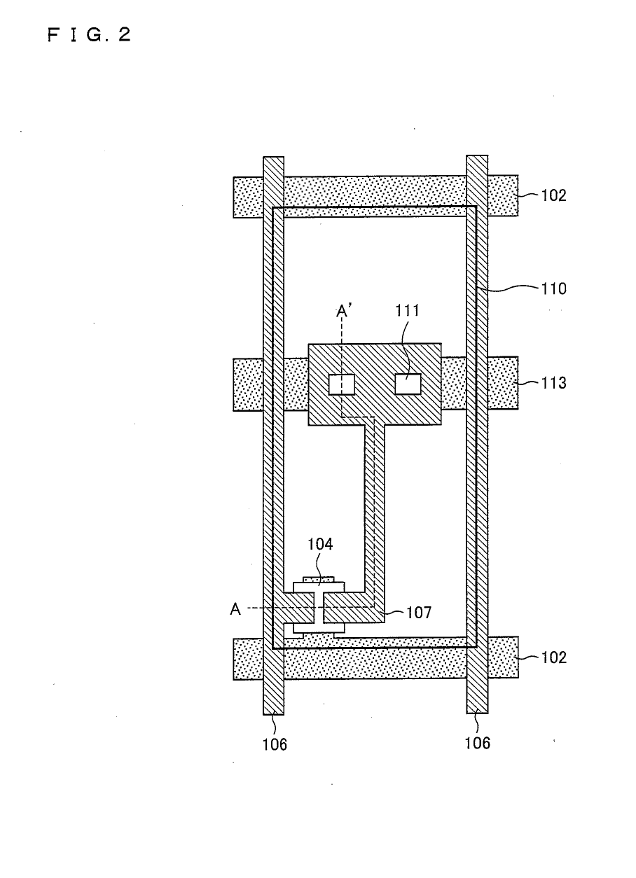

With reference to FIGS. 1 and 2, the following description discusses how the active matrix substrate is configured in accordance with the present embodiment.

The active matrix substrate has a display region and a non-display region provided outside the display region. In the display region, pixel electrodes (transparent electrode) 110 are provided in matrix, and an image to be viewed by a viewer is displayed. In the non-display region, no display is viewed by the viewer. One of the pixel electrodes 110 provided in the display region is exemplified in FIGS. 1 and 2. FIG. 1 is a cross sectional view showing the active matrix substrate in accordance with the present embodiment. FIG. 2 is a plan view showing the active matrix substrate in accordance with the present embodiment. Note that FIG. 1 is the cross sectional view taken on the line A-A′ in FIG. 2.

According to the present embodiment, the active matrix substrate has a configuration as shown in FIG. 1 in which gate lines (lines) 102, source lines (lines) 106, compensating capacitive electrodes (lines) 113, and drains electrodes (lines) 107 are provided above a glass substrate 101, and gate insulating films 103, semiconductor layers 104, N⁺ contact layers 105, a passivation film 108, and an interlayer insulating film 109 are provided between the lines and the electrodes. The pixel electrodes 110 are provided on the interlayer insulating film 109.

According to the active matrix substrate, the gate lines 102 and the source lines 106 are provided so as to intersect each other, and pixel sections including respective TFTs are provided near respective intersections of the gate lines 102 and the source lines 106 (see FIG. 2). The drain electrodes 107 and the pixel electrodes 110 are provided for the respective TFTs. Each of the compensating capacitive electrodes 113 is provided so that a compensation capacitance is defined by the each of the compensating capacitive electrodes 113 and a corresponding one of the pixel electrodes 110.

With reference to FIG. 1, the following description discusses in detail how the gate lines 102 provided in the display region on the active matrix substrate are configured. The following description further discusses how lines provided in the display region on the active matrix substrate of the present embodiment (for easy description, the “lines provided in the display region on the active matrix substrate of the present embodiment” are hereinafter referred to simply as “lines”) are configured. Note that, in the present Specification, the “lines” encompass lines, electrodes, and the like. According to the present embodiment, the “lines” indicate the gate lines 102, the source lines 106, the drain electrodes 107, and/or the compensating capacitive electrodes 113. It can be said that the display region is, in other words, a region where external light reaches after entering a display surface of the display panel from a viewer's side. The external light indicates light emitted from a room light provided outside the display panel, sunlight, and the like. According to the active matrix substrate shown in FIG. 1, the external light indicates the light which has entered from a pixel electrode 110 side.

As shown in FIG. 1, each of the gate lines 102 is made up of a copper oxide layer (uppermost layer) 102c, a copper layer (first layer) 102b, and a titanium layer (second layer) 102a. The copper oxide layer 102c, the copper layer 102b, and the titanium layer 102a are described in detail below.

(Copper Oxide Layer 102C)

The copper oxide layer 102c is provided as an uppermost layer of the gate line 102. The copper oxide layer 102c is a layer containing an oxide of copper (Cu) (first metal). Examples of the oxide of copper encompass copper (II) oxide (CuO), copper (I) oxide (Cu₂O), and the like. Note that a nitride of copper, an oxide of titanium (Ti) or molybdenum (Mo), or the like can be substituted for the oxide of copper contained in the copper oxide layer 102c. That is, according to the present invention, the first metal is not limited to Cu, but can be Ti, Mo, or the like. Examples of such oxide and nitride encompass copper nitride (Cu₃N), titanium dioxide (TiO₂), molybdenum trioxide (MoO₃), molybdenum dioxide (MoO₂), and the like.

Each of the oxides and the nitrides described above has a small reflectance. As such, the copper oxide layer 102c has a small reflectance. Since the uppermost layer of the gate line 102 of the present embodiment is the copper oxide layer 102c, a reflectance on an uppermost layer side of the gate line 102 is small. It is therefore possible in the liquid crystal display panel to prevent the external light from being reflected by the lines, and thereby to improve a contrast in a bright room.

The copper oxide layer 102c preferably has a thickness of 50 Å to 2000 Å, and more preferably has a thickness of approximately 500 Å.

(Copper Layer 102b)

The copper layer 102b is a layer containing copper. For example, pure copper or the like can be used as copper. The copper has a small resistance, and it is therefore possible for the line containing copper to have a small resistance.

Note that, instead of copper, a copper alloy can be contained in the copper layer 102b. For example, a copper-magnesium alloy (CuMg), a copper-manganese alloy (CuMn), a copper-aluminum alloy (CuAl), a copper-titanium alloy (CuTi), a copper-zirconium alloy (CuZr), a copper-molybdenum alloy (CuMo), or the like can be used as the copper alloy. The use of such a metal allows the line to have a small resistance.

The copper layer 102b preferably has a thickness of 1000 Å to 10000 Å, more preferably has a thickness of 1000 Å to 4000 Å, and most preferably has a thickness of approximately 3000 Å. It is further preferable that the thickness of the copper layer 102b is adjusted so that it is possible to obtain a desired resistance of the line.

(Titanium Layer 102a)

The titanium layer 102a is a layer containing titanium (Ti). The titanium layer 102a preferably has a thinness of 50 Å to 500 Å, and more preferably has a thickness of 300 Å to 500 Å.

Note that the present invention is not limited to the configuration that the second layer is made from titanium. The second layer can be made from molybdenum or a molybdenum alloy. Examples of the molybdenum alloy encompass a molybdenum-tungsten alloy (MoW), a molybdenum-niobium alloy (MoNb), a molybdenum-neodymium alloy (MoNd), a molybdenum-titanium alloy (MoTi), a molybdenum-tantalum alloy (MoTa), a molybdenum-nickel alloy (MoNi), a molybdenum-indium alloy (MoIn), a molybdenum-aluminum alloy (MoAl), and the like.

Note, also, that the gate line 102 has a good tapered shape. The good tapered shape indicates, for example, a shape in which an end part defines a smoothly inclined surface or the like. In a contrast, examples of a bad shape encompass a shape in which the layers in the gate line 102 are stacked so that their end parts define a step-like surface, a shape in which the layers in the gate line 102 are stacked so that a width of an upper one of the layers is greater than that of a lower one of the layers, and the like.

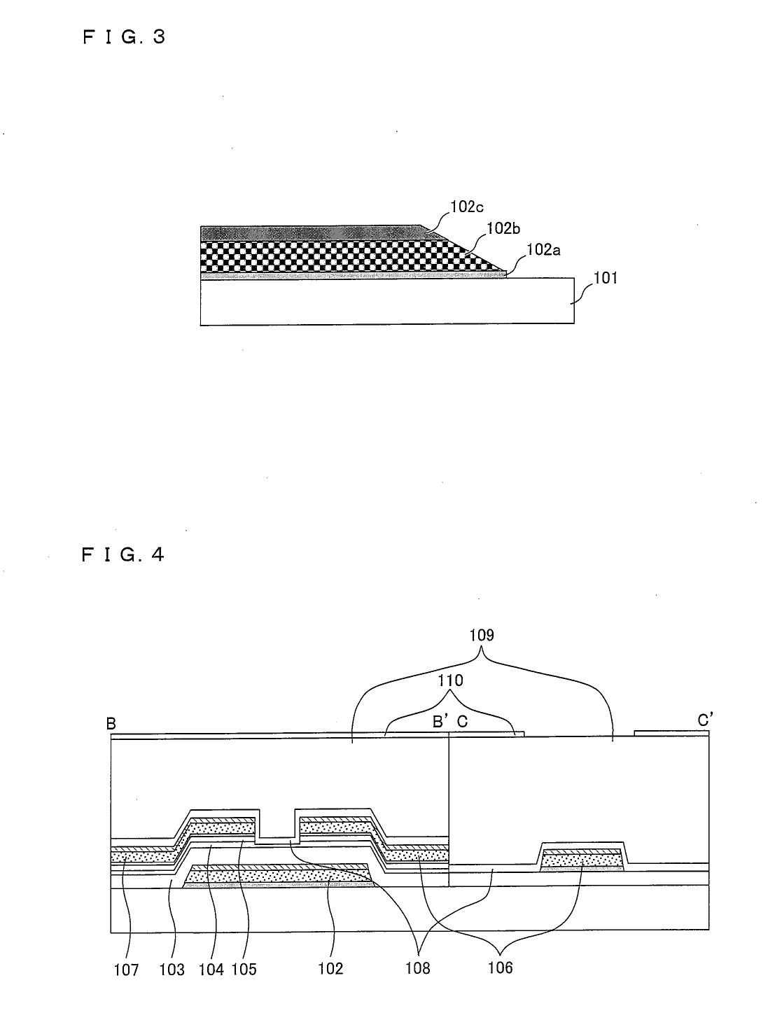

FIG. 3 shows an example of the good tapered shape. FIG. 3 is a cross sectional view showing the gate line 102 in accordance with the present embodiment.

According to the gate line 102, the copper layer 102b is provided so as to have a bottom surface whose width (i) is substantially identical with a width of an upper surface of the titanium layer 102a and (ii) becomes narrower as the copper layer 102b is farther from the titanium layer 102a (see FIG. 3). Further, the copper oxide layer 102c is provided so as to have a bottom surface whose width (i) is substantially identical with a width of an upper surface of the copper layer 102b and (ii) becomes narrower as the copper oxide layer 102c is farther from the copper layer 102b. According to the gate line 102 as a whole, the gate line 102 thus has a narrower width from a bottom part of the gate line 102 toward an upper part of the gate line 102.

Since the line thus has the good tapered shape, it is possible to prevent copper contained in the copper layer 102b of the line from being in contact with a base such as the glass substrate 101. Further, since the line thus has the good tapered shape, it is possible for the gate insulating film 103 or the like to suitably cover an upper one of the layers in the line such as the copper layer 102b, in a tapered part. In contrast, in a case where the line has a bad tapered shape, there may be a case that the copper layer 102b and/or the like is not completely covered by the gate insulating film 103 or the like in a tapered part. This gives rise to a risk that film exfoliation, a disconnection between adjacent steps of the step-like surface, and/or the like is caused.

The gate line 102 thus has the configuration. Note that each of the source line 106, the drain electrode 107, and the compensating capacitive electrode 113 has a configuration similar to that of the gate line 102. As such, the description of the gate line 102 is applied correspondingly to the source line 106, the drain electrode 107, and the compensating capacitive electrode 113, so that description of the source line 106, the drain electrode 107, and the compensating capacitive electrode 113 is omitted here. That is, the description of the copper oxide layer 102c, the copper layer 102b, and the titanium layer 102a of the gate line 102 is applied correspondingly to copper oxide layers (uppermost layers) (106c, 107c, and 113c), copper layers (first layers) (106b, 107b, and 107a), and titanium layers (second layers) (106a, 107a, and 113a) of respective of the source line 106, the drain electrode 107, and the compensating capacitive electrode 113.

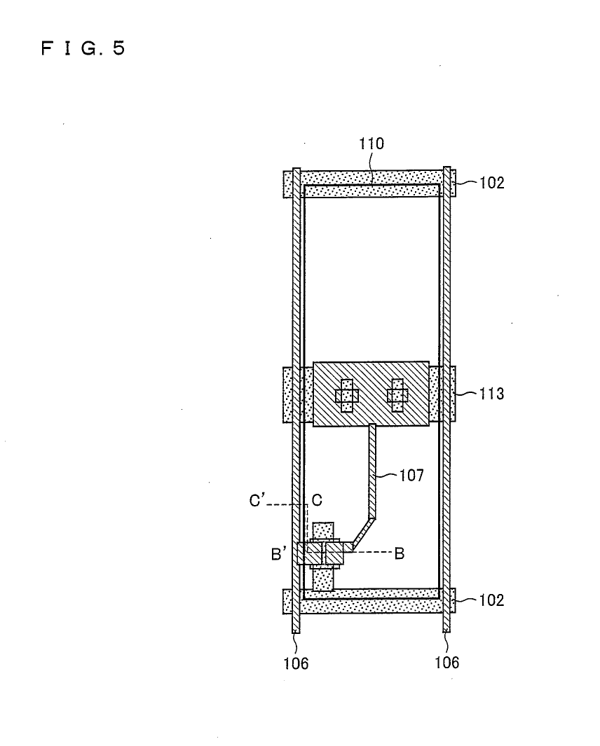

With reference to FIGS. 4 and 5, the following description discusses another pixel electrode 110 in the active matrix substrate in accordance with the present embodiment. FIG. 4 is a cross sectional view showing the active matrix substrate in accordance with the present embodiment. FIG. 5 is a plan view showing the active matrix substrate in accordance with the present embodiment. FIG. 4 is the cross sectional view taken on lines B-B′ and C-C′ in FIG. 5.

As shown in a region B-B′ of FIG. 4, a gate line 102, a source line 106, and a drain electrode 107 each provided for another pixel electrode 110 are tri-layered as described above. Further, even in a region C-C′ where (i) a boundary between two adjacent pixel electrodes 110 is defined, (ii) only the source line 106 is provided as the line, and (iii) no pixel electrode 110 is provided, the source line 106 is tri-layered as described above.

According to the active matrix substrate of the present embodiment, the copper oxide layers (102c, 106c, 107c, and 113c) are thus provided as the uppermost layers of the respective of the gate line 102, the source line 106, the drain electrode 107, and the compensating capacitive electrode 113 provided in the display region, i.e., the region where the external light reaches. This can prevent the external light from being reflected by the lines. It is therefore possible to fabricate a display panel whose contrast in a bright room is high.

Note that the lines, which are provided in the display region on the substrate of the present invention, are not particularly limited to the three-layered structures, provided that the lines are made up of multiple layers. The lines can therefore be bi-layered or multi-layered in which four (4) or more layers are stacked. Uppermost layers of the respective lines should contain (i) an oxide of copper, titanium, or molybdenum or (ii) a nitride of copper. Layers other than the uppermost layers are not particularly limited.

The gate insulating film 103 can be made from, for example, silicon nitride (SiNx), silica dioxide (SiO₂), or the like. Alternatively, a stack of a layer made from SiNx and a layer made from SiO₂ can be used as the gate insulating film 103. It is preferable that the gate insulating film 103 has a thickness of 1000 Å to 5000 Å.

The semiconductor layer 104 can be made from, for example, amorphous silicon or the like. Alternatively, the semiconductor layer 104 can be made from an oxide semiconductor such as zinc oxide (ZnO) or an amorphous thin film (IGZO) having a composition of indium oxide-gallium oxide-zinc oxide. It is preferable that the semiconductor layer 104 has a thickness of 300 Å to 3000 Å.

The N⁺ contact layers 105 are not limited to specific ones, provided that they are electrode contact layers to which a high concentration of an n-type impurity is added. For example, the N⁺ contact layers 105 can be made from N⁺ amorphous silicon or the like. It is preferable that the N⁺ contact layer 105 has a thickness of 500 Å to 1500 Å.

The passivation film 108 can be made from, for example, silicon nitride (SiNx), silica dioxide (SiO₂), or the like. It is preferable that the passivation film 108 has a thickness of 500 Å to 3000 Å.

It is preferable that the interlayer insulating film 109 has a photosensitivity. For example, the interlayer insulating film 109 can be made from a photosensitive acrylic resin or the like. It is preferable that the interlayer insulating film 109 has a thickness of 1 μm to 4 μm.

The pixel electrode 110 can be made from, for example, a transparent conductive material such as indium tin oxide (ITO) or indium oxide-zinc oxide (IZO). It is preferable that the pixel electrode 110 has a thickness of 100 Å to 2000 Å.

Further, according to the active matrix substrate of the present embodiment, the drain electrodes 107 and the pixel electrodes 110 are electrically connected to each other in respective contact hole sections (connection sections) 111. As shown in FIG. 1, in the contact hole section 111, part of the copper oxide layer 107c of the drain electrode 107 is removed, so that the copper layer 107b is exposed. The copper layer 107b thus exposed and the pixel electrode 110 are in contact with each other in the contact hole section 111. A shape of the contact hole section 111 is not limited to a quadrangle shape as shown in FIG. 2, provided that a size of the contact hole section 111 is large enough to allow sufficient contact between the drain electrode 107 and the pixel electrode 110. For example, the shape of the contact hole section 111 can be a circle shape. Shape and size of the part of the copper oxide layer 107c to be removed can be similar to the shape and size of the contact hole section 111. The size of the part of the copper oxide layer 107c to be removed can be smaller than the size of the contact hole section 111. Above all, it is preferable that the size of the part of the copper oxide layer 107c to be removed is large enough to allow a sufficient contact between the copper layer 107b and the pixel electrode 110. A connection resistance generated when the copper oxide layer 107c and the pixel electrode 110 are in contact with each other is large. The copper oxide layer 107c is, however, removed in the contact hole section 111, and the copper layer 107b and the pixel electrode 110 are therefore in contact with each other. This allows the pixel electrode 110 and the drain electrode 107 to be connected with each other at a part where a connection resistance is small.

<Steps of Manufacturing Active Matrix Substrate>

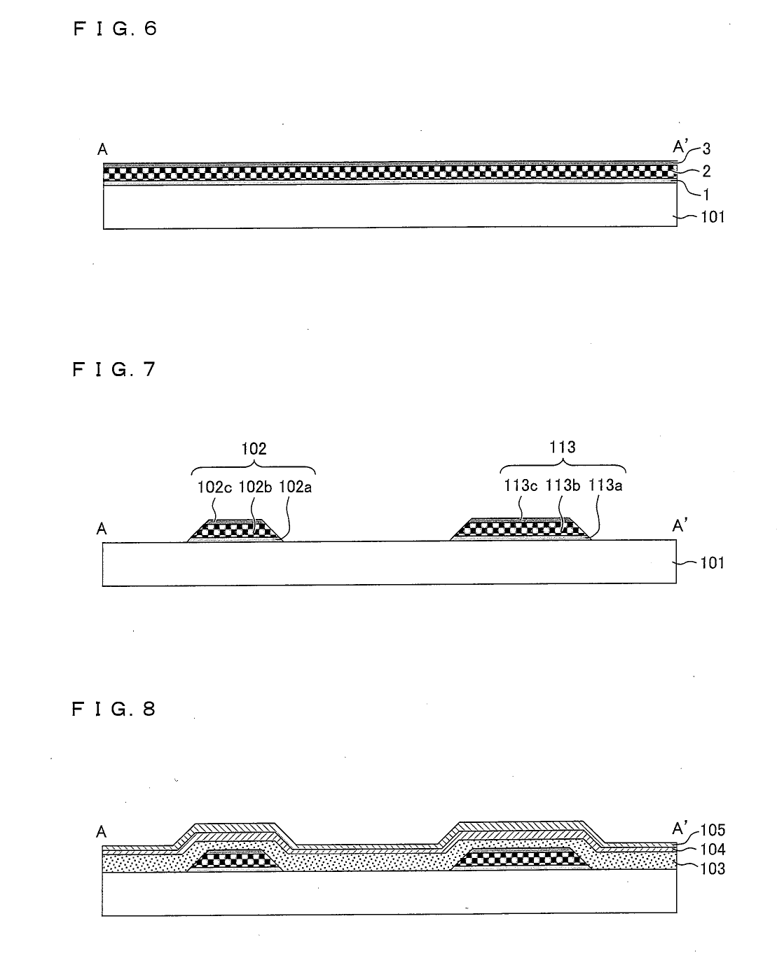

With reference to FIGS. 6 through 16, the following descriptions (1) through (12) discuss the steps of manufacturing the active matrix substrate of the present embodiment. Note that the steps are discussed sequentially from the description (1) to the description (12). Each of FIGS. 6 through 16 is a cross sectional view showing that a corresponding one of the steps is carried out with respect to the active matrix substrate of the present embodiment. Note that each of FIGS. 6 through 16 shows a configuration of a cross section of the active matrix substrate that has been subjected to the corresponding one of the steps. Note also that the following description discusses the steps for manufacturing the active matrix substrate having a configuration shown in FIG. 1. Each of FIGS. 6 through 16 is the cross sectional view taken on the line A-A′ in FIG. 2.

(1) Step of Depositing First Metal Films

First, the step of depositing the first metal films is carried out (see FIG. 6). FIG. 6 is the cross sectional view showing that the step of depositing the first metal films is carried out with respect to the active matrix substrate in accordance with the present embodiment.

According to the step of depositing the first metal films, first, a titanium film 1 and a copper film 2 are deposited on the glass substrate 101 by sputtering. Then, a film made from CuO is deposited as the copper oxide film 3 by reactive sputtering in which copper and oxygen are reacted to each other by use of a sputtering gas prepared by adding oxygen to normal argon. In the sputtering gas, O₂ preferably has a partial pressure of 10% to 30%, and more preferably has a partial pressure of approximately 10%.

Instead of copper oxide, copper nitride such as a nitride of copper can be deposited as the copper oxide film 3. In this case, reactive sputtering can be employed in which copper and nitride are reacted to each other by use of a sputtering gas prepared by adding nitride (N₂), instead of oxygen, to argon. In the sputtering gas, N₂ preferably has a partial pressure of 10% to 90%, and more preferably has a partial pressure of approximately 50%.

(2) Step of Forming Gate Line 102

Next, the step of forming the gate line 102 is carried out (see FIG. 7). FIG. 7 is the cross sectional view showing that the step of forming the gate line 102 is carried out with respect to the active matrix substrate in accordance with the present embodiment.

According to the step of forming the gate line 102, resist patterns are formed by photolithography, and patterns of respective of the gate line 102 and the compensating capacitive electrode 113 are formed by wet etching. Thereafter, the resist are removed, and cleaning is carried out.

It is preferable that an etching solution containing hydrogen peroxide, inorganic acid, a fluorine compound, and water is employed as an etching solution for use in the wet etching. Examples of inorganic acid encompass hydrochloric acid, sulfuric acid, nitric acid, phosphoric acid, and the like. Examples of the fluorine compound encompass fluorinated acid, ammonium fluoride, potassium fluoride, and the like. It is preferable that a concentration of the fluorine compound is adjusted so as not to adversely affect the glass substrate 101, which is the base, and the like. The etching solution can further contain organic acid. Examples of organic acid encompass carboxylic acid, amino acid, citric acid, tartaric acid, oxalic acid, and the like. For example, an etching solution disclosed in U.S. Pat. No. 7,008,548 (the patent literature 1) or the like can be used as the etching solution.

Note that, in a case of employing an etching solution containing, for example, (i) hydrogen peroxide, (ii) hydrochloric acid (HCL) serving as inorganic acid, and (iii) fluorinated acid serving as the fluorine compound, the Cu layer is etched by reactions represented by the following formulae (A) and (B), whereas the Ti layer is etched by a reaction represented by the following formula (C):

Cu+H₂O₂→CuO+H₂O (A);

CuO+2HCL→CuCl₂+H₂O (B); and

Ti+4HF→TiF₄+H₂ (C).

The reactions represented by the respective formulae (A) and (B) have faster reaction rates than the reaction represented by the formula (C). Since the fluorine compound adversely affects the glass substrate 101 which is the base, it is not possible to employ an increased concentration of the fluorine compound. The Cu layer is therefore etched faster than the Ti layer is. In a case where, as with the present embodiment, the line has, for example, a three-layer configuration in which the CuO layer, the Cu layer, and the Ti layer are stacked, an etching speed of the Cu layer is suppressed because the reaction represented by the formula (B) contributes to an etching speed of the CuO layer. This ultimately allows the line to have a good tapered shape as early described. It is possible to obtain a similar effect even in a case of employing, instead of the CuO layer, a layer containing an oxide such as CuO₂, a nitride such as copper nitride, or the like.

According to the step of forming the gate line 102, such an effect allows the gate line 102 and the compensating capacitive electrode 113 to have a good tapered shape as early described.

(3) Step of Depositing Gate Insulating Film 103 and Semiconductor Layer 104

Then, the step of depositing the gate insulating film 103 and the semiconductor layer 104 is carried out (see FIG. 8). FIG. 8 is the cross sectional view showing that the step of depositing the gate insulating film 103 and the semiconductor laser 104 is carried out with respect to the active matrix substrate in accordance with the present embodiment.

According to the step, (i) silicon nitride (SiNx) serving as the gate insulating film 103, (ii) amorphous silicon serving as the semiconductor layer 104, and (iii) N⁺ amorphous silicon serving as the N⁺ contact layer 105 are continuously deposited by a CVD method.

According to the present embodiment, the gate insulating film 103, the semiconductor layer 104, and the N+ contact layer 105 are continuously deposited. However, the present invention is not limited to this, and therefore the gate insulating film 103, the semiconductor layer 104, and the N⁺ contact layer 105 can be independently deposited.

(4) Step of Forming Pattern of Semiconductor Layer 104

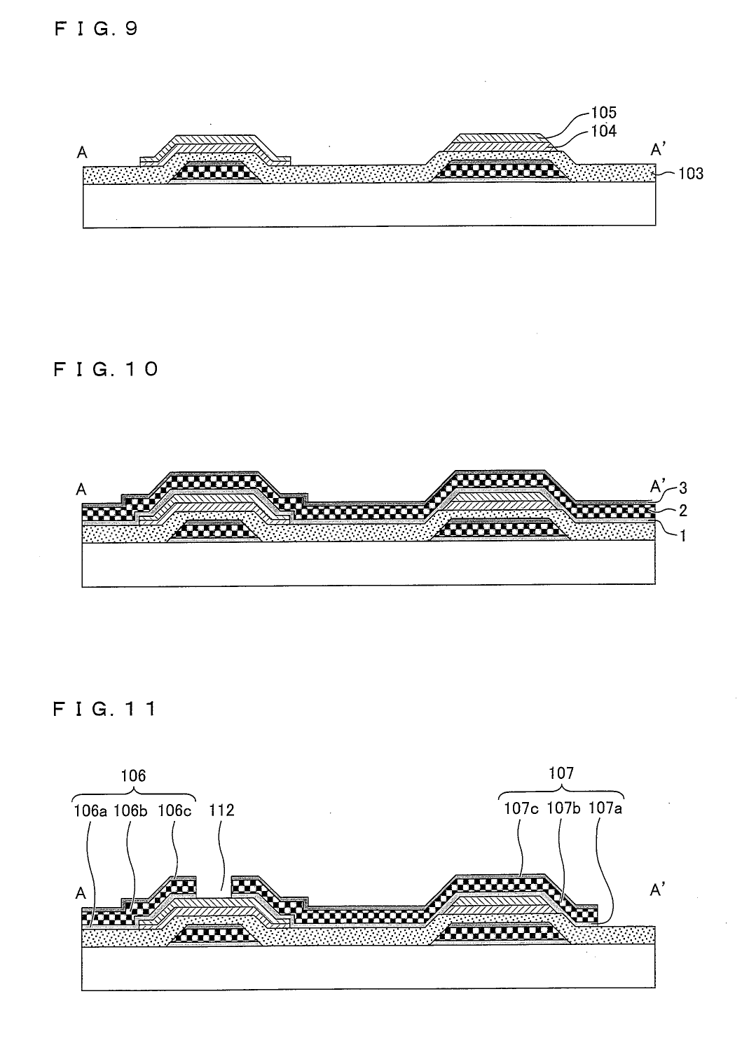

Then, the step of forming a pattern of the semiconductor layer 104 is carried out (see FIG. 9). FIG. 9 is the cross sectional view showing that the step forming the pattern of the semiconductor layer 104 is carried out with respect to the active matrix substrate in accordance with the present embodiment.

According to the step of forming the pattern of the semiconductor layer 104, a resist pattern is formed by photolithography, and then, the semiconductor layer 104 and the N⁺ contact layer 105 are etched by, for example, a method such as dry etching so that a pattern is formed. After this, the resist is removed, and then cleaning is carried out.

(5) Step of Depositing Second Metal Films

Then, the step of depositing the second metal films is carried out (see FIG. 10). FIG. 10 is the cross sectional view showing that the step of depositing the second metal films is carried out with respect to the active matrix substrate in accordance with the present embodiment.

According to the step of providing the second metal films, another titanium film 1, another copper film 2, and another copper oxide film 3 are deposited by a method similar to the method employed in (1) the step of depositing the first metal films.

(6) Step of Forming Pattern of Source Line 106

Then, the step of forming a pattern of the source line 106 is carried out (see FIG. 11). FIG. 11 is the cross sectional view showing that the step of forming the pattern of the source line 106 is carried out with respect to the active matrix substrate in accordance with the present embodiment. According to the step of forming the pattern of the source line 106, (i) resist patterns are formed by photolithography, and (ii) patterns of respective of the source line 106 and the drain electrodes 107 are formed, by using the respective resist patterns, by wet etching. The wet etching can be carried out in a way similar to the wet etching carried out in (2) the step of forming the gate line 102. This allows the source line 106 and the drain electrode 107 to have respective good tapered shapes as early described.

(7) Step of Etching Channel Section 112

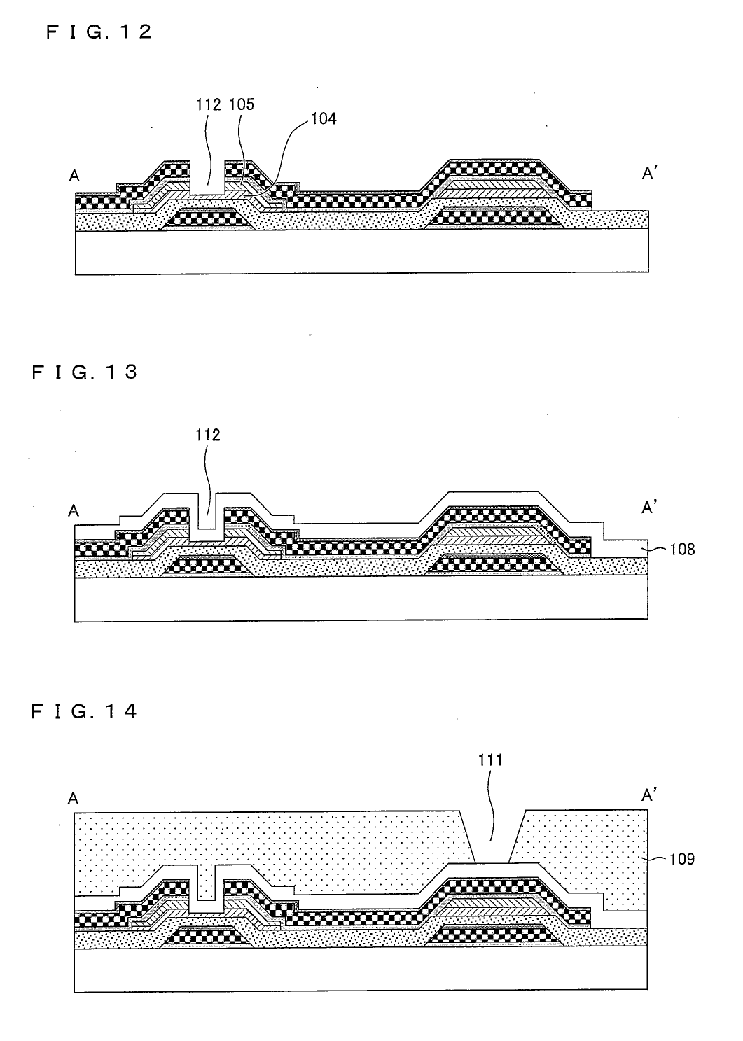

Then, the step of etching the channel section 112 is carried out (see FIG. 12). FIG. 12 is the cross sectional view showing that the step of etching the channel section 112 is carried out with respect to the active matrix substrate in accordance with the present embodiment.

According to the step of etching the channel section 112, part of the N⁺ contact layer 105 and part of the semiconductor layer 104 are removed, by dry etching, in a channel section 112 between the source line 106 and the drain electrode 107. This causes electrical separation of the source line 106 and the drain electrode 107. After this, the resist is removed, and then cleaning is carried out.

(8) Step of Depositing Passivation Film 108

Then, the step of depositing the passivation film 108 is carried out (see FIG. 13). FIG. 13 is the cross sectional view showing that the step of depositing the passivation film 108 is carried out with respect to the active matrix substrate in accordance with the present embodiment.

According to the step of depositing the passivation film 108, silicon nitride is deposited as the passivation film 108 by a CVD method.

(9) Step of Forming Interlayer Insulating Film 109

Then, the step of forming the interlayer insulating film 109 is carried out (see FIG. 14). FIG. 14 is the cross sectional view showing that the step of forming the interlayer insulating film 109 is carried out with respect to the active matrix substrate in accordance with the present embodiment.

According to the step of forming the interlayer insulating film 109, a photosensitive acrylate resin is deposited as the interlayer insulating film 109, and a pattern of the contact hole section 111 is formed by photolithography.

(10) Step of Etching Contact Hole Section 111

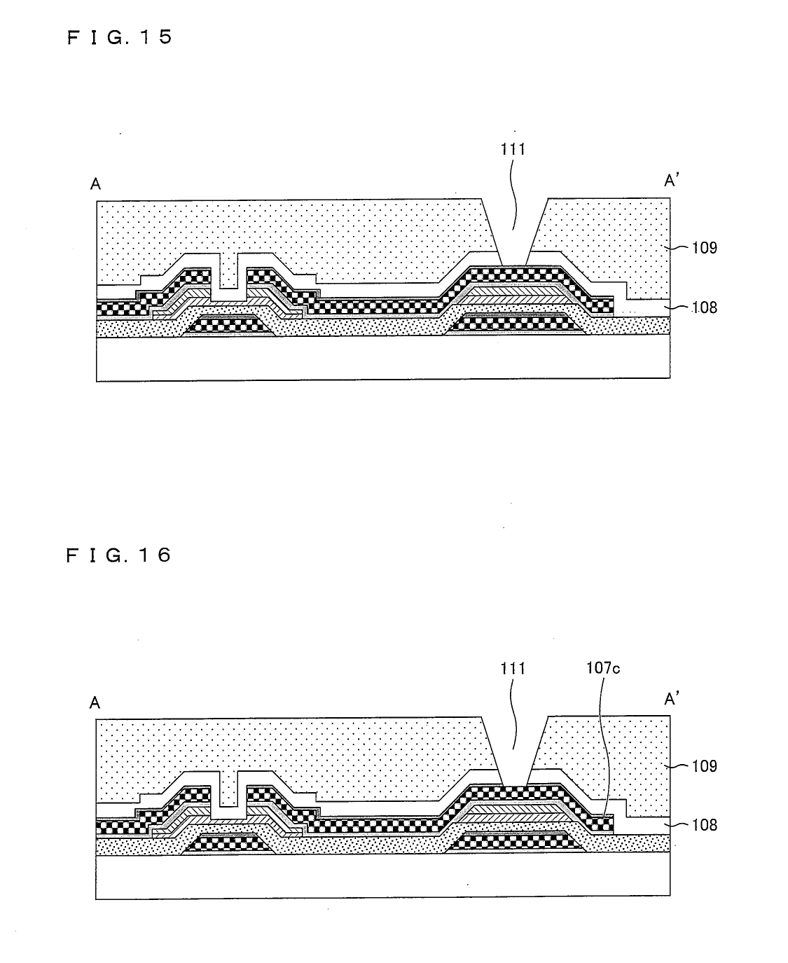

Then, the step of etching the contact hole section 111 is carried out (see FIG. 15). FIG. 15 is the cross sectional view showing that the step of etching the contact hole section 111 is carried out with respect to the active matrix substrate in accordance with the present embodiment.

According to the step of etching the contact hole section 111, dry etching is carried out by using the interlayer insulating film 109 as a mask. This causes the passivation film 108 to be removed from the contact hole section 111.

(11) Step of Removing Copper Oxide Layer 107c

Then, the step of removing the copper oxide layer 107c is carried out (see FIG. 16). FIG. 16 is the cross sectional view showing that the step of removing the copper oxide layer 107c is carried out with respect to the active matrix substrate in accordance with the present embodiment.

According to the step of removing the copper oxide layer 107c, the copper oxide layer 107c of the drain electrode 107 is removed from the contact hole section 111 by wet etching. Hydrochloric acid, nitric acid, or the like, for example, can be used as an etching solution for use in the wet etching method.

(12) Step of Forming Pixel Electrode 110

Then, the step of forming the pixel electrode 110 is carried out, so that manufacturing of the active matrix substrate shown in FIG. 1 is completed.

According to the step of forming the pixel electrode 110, first, a transparent conductive material is deposited, by sputtering, as a film to form the pixel electrode 110. Then, a resist pattern is formed, by photolithography, with respect to the film thus formed. After this, wet etching is carried out so as to form a pattern of the pixel electrode 110. Subsequently, a resist is removed, and then cleaning is carried out. Salt iron, oxalic acid, a solution of a mixture of phosphoric acid, acetic acid, and nitric acid, or the like, for example, can be used as an etching solution for use in the wet etching.

Note here that, in the contact hole section 111, since the copper oxide layer 107c has been removed, the pixel electrode 110 and the copper layer 107b are in contact with each other. It is therefore possible that the pixel electrode 110 and the drain electrode 107 are connected with each other so that a connection part where they are connected to each other has a low resistance.

The active matrix substrate of the present embodiment is manufactured by the steps described above. Note, however, that the present invention is not limited to the materials and the thicknesses of the respective layers. A conventionally and generally used material can be used as a material of the active matrix substrate.

Note that the substrate of the present invention for use in a display panel is not limited to an active matrix substrate and can be therefore, for example, a passive matrix substrate. The substrate of the present embodiment for use in a display panel can be also used in, for example, a display panel in which organic EL, inorganic El, or the like is employed.

According to the substrate of the present invention for use in a display panel, it is preferable that a first layer made from copper or a copper alloy is provided below the uppermost layer in the line.

An electric resistance of copper or copper alloy is small. Thus, according to the configuration, an electric resistance of the line can be small.

Furthermore, according to the substrate of the present invention for use in the display panel, it is preferable that a second layer made from titanium is provided below the first layer in the line.

Furthermore, according to the substrate of the present invention for use in the display panel, it is preferable that a second layer made from molybdenum or a molybdenum alloy is provided below the first layer in the line.

According to each of the configurations, it is possible to secure close adhesion of the line to the base on which the line is provided. Further, it is also possible to prevent copper or the copper alloy contained in the first layer of the line to spread to the base. In forming of the line, the multiple layers are etched, by single etching, by using the etching solution containing hydrogen peroxide, inorganic acid, and a fluorine compound. In such circumstances, etching of the oxide or nitride in the uppermost layer causes suppression of the etching speed of the copper or the copper alloy in the first layer. This ultimately allows the line to easily have the good tapered shape.

Furthermore, it is preferable that the substrate of the present invention for use in the display panel further includes a connection section in which the line and a transparent electrode provided above the line are connected, in the connection section, part of the uppermost layer in the line being removed, so that an exposed part of the first layer and the transparent electrode are in contact with each other.

A connection resistance generated when the uppermost layer of the line, which is made from the oxide of the first metal or the nitride of copper, and the transparent electrode are connected to each other is large. According to the configuration, however, the uppermost layer of the line is removed from the connection section in which the line and the transparent electrode are connected to each other. As such, the first layer of the line and the transparent electrode are in contact with each other. This allows the line and the transparent electrode to be connected to each other at a region where a connection resistance is small.

Furthermore, according to the substrate of the present invention for use in the display panel, it is preferable that the line is at least one selected from the group consisting of a gate line, a source line, a drain electrode, and a compensating capacitive electrode.

According to the configuration, it is possible to fabricate a display panel in which it is possible to further prevent the external light from being reflected and thereby to further improve the contrast in the bright room.

The present invention is not limited to any of the aforementioned embodiments, but can be altered within the scope of the following claims. That is, an embodiment realized by combining technical means modified as appropriate within the scope of the claims is included within the technical scope of the present invention.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

### INDUSTRIAL APPLICABILITY

The present invention can provide a substrate for use in a display panel in which substrate it is possible to prevent external light from being reflected and thereby to improve a contrast in a bright room. The present invention can further provide a display panel including the substrate. The present invention therefore can be suitably employed in manufacturing of a high-quality display apparatus.

### REFERENCE SIGNS LIST

102a, 106a, 107a, 113a. titanium layer (second layer)
102b, 106b, 107b, 113b. copper layer (first layer)
102c, 106c, 107c, 113c. copper oxide layer (uppermost layer)
102. gate line (line)
103. gate insulating film
104. semiconductor layer
105. N⁺ contact layer
106. source line (line)
107. drain electrode (line)
108. passivation film
109. interlayer insulating film
110. pixel electrode (transparent electrode)
111. contact hole section (connection section)
113. compensating capacitive electrode (line)

1. A substrate for use in a display panel, comprising:
a line provided in a display region on the substrate, the line being made up of a plurality of layers whose uppermost layer is made from (i) an oxide of a first metal selected from the group consisting of copper, titanium, and molybdenum or (ii) a nitride of copper.

2. The substrate as set forth in claim 1, wherein:
a first layer made from copper or a copper alloy is provided below the uppermost layer in the line.

3. The substrate as set forth in claim 2, wherein:
a second layer made from titanium is provided below the first layer in the line.

4. The substrate as set forth in claim 2, wherein:
a second layer made from molybdenum or a molybdenum alloy is provided below the first layer in the line.

5. The substrate as set forth in claim 2, further comprising:
a connection section in which the line and a transparent electrode provided above the line are connected,
in the connection section, part of the uppermost layer in the line being removed, so that an exposed part of the first layer and the transparent electrode are in contact with each other.

6. The substrate as set forth in claim 1, wherein:
the line is at least one selected from the group consisting of a gate line, a source line, a drain electrode, and a compensating capacitive electrode.

7. A display panel, comprising a substrate recited in claim 1.
